(19) United States
(12) Patent Application Publication
(10) Pub. No.: US 2024/0250091 A1
(43) Pub. Date: Jul. 25, 2024

(54) SEMICONDUCTOR DEVICE

(71) Applicant: Japan Display Inc., Tokyo (JP)

(72) Inventors: Masahiro WATABE, Tokyo (JP); Hajime WATAKABE, Tokyo (JP); Masashi TSUBUKU, Tokyo (JP); Toshinari SASAKI, Tokyo (JP); Marina MOCHIZUKI, Tokyo (JP); Takaya TAMARU, Tokyo (JP); Ryo ONODERA, Tokyo (JP)

(73) Assignee: Japan Display Inc., Tokyo (JP)

(21) Appl. No.: 18/411,028

(22) Filed: Jan. 12, 2024

(30) Foreign Application Priority Data
Jan. 25, 2023 (JP) 2023-009543

(51) Int. Cl. H01L 27/12; G02F 1/1368; H01L 29/786

(52) U.S. Cl. CPC H01L 27/124; H01L 27/1225; H01L 29/7869; G02F 1/1368

(57) ABSTRACT

A semiconductor device includes an oxide semiconductor layer including a polycrystalline structure, a gate electrode facing the oxide semiconductor layer, a gate insulating layer between the oxide semiconductor layer and the gate electrode, a first transparent conductive layer connected to the oxide semiconductor layer, and a second transparent conductive layer arranged in the same layer as the first transparent conductive layer and separated from the first transparent conductive layer, wherein crystallizability of the first transparent conductive layer is different from crystallizability of the second transparent conductive layer.

### CROSS-REFERENCE TO RELATED APPLICATION

This application claims the benefit of priority to Japanese Patent Application No. 2023-009543, filed on Jan. 25, 2023, the entire contents of which are incorporated herein by reference.

### FIELD

One embodiment of the present invention relates to a semiconductor device.

### BACKGROUND

Recently, a transistor using an oxide semiconductor as a channel has been developed in place of an amorphous silicon, a low-temperature polysilicon, and a single-crystal silicon (e.g., Japanese laid-open patent publication No. 2014-146819 and Japanese laid-open patent publication No. 2015-159315). The transistor using the oxide semiconductor as the channel is formed in a simple-structured, low-temperature process similar to a transistor using an amorphous silicon as a channel. It is known that the transistor using the oxide semiconductor as the channel has higher mobility than the transistor using the amorphous silicon as the channel and has a very low off-current.

In recent years, due to the advancement in the technology for reducing of the size of a pixel in modern display devices, it has also become possible to reduce the width of wiring and the size of transistors. However, there is a limitation to these reductions, and an aperture ratio is reduced due to arrangements of a metal layer and a semiconductor layer constituting a pixel circuit. Therefore, the development for using the oxide semiconductor layer as the channel of the transistor in the pixel circuit, which obtains sufficient characteristics in spite of its miniaturized size is progressing.

In the transistor using the low-temperature polysilicon as the channel, a silicon layer and a transparent conductive layer (for example, A mixture of indium oxide and tin oxide (ITO)) used as a pixel electrode cannot be directly in contact with each other. Therefore, it is necessary to provide a pedestal of a metal layer between the silicon layer and the transparent conductive layer. If such a pedestal is arranged in a display region of a pixel, there is a problem whereby an aperture ratio of the pixel is reduced. The technical idea regarding such a contact structure is common to the transistor using the oxide semiconductor as the channel, and the structure forming the transparent conductive layer on the pedestal of the metal layer is commonly used. Further, even in a transistor using an oxide semiconductor layer is used as a channel, in a structure in which a transparent conductive layer is directly in contact with an oxide semiconductor layer in a source region and a drain region, contact resistance between the oxide semiconductor layer and the transparent conductive layer may be increased depending on a manufacturing process.

### SUMMARY

A display device according to an embodiment of the present disclosure includes: an oxide semiconductor layer including a polycrystalline structure, a gate electrode facing the oxide semiconductor layer, a gate insulating layer between the oxide semiconductor layer and the gate electrode, a first transparent conductive layer connected to the oxide semiconductor layer, and a second transparent conductive layer arranged in the same layer as the first transparent conductive layer and separated from the first transparent conductive layer, wherein crystallizability of the first transparent conductive layer is different from crystallizability of the second transparent conductive layer.

### BRIEF DESCRIPTION OF DRAWINGS

FIG. 1 is a cross-sectional view showing an outline of a display device according to an embodiment of the present invention.

FIG. 2 is a plan view showing an outline of a display device according to an embodiment of the present invention.

FIG. 3 is a plan view showing a layout of each layer in a display device according to an embodiment of the present invention.

FIG. 4 is a plan view showing a layout of one or more layers in a display device according to an embodiment of the present invention.

FIG. 5 is a plan view showing a layout of one or more layers in a display device according to an embodiment of the present invention.

FIG. 6 is a plan view showing a layout of one or more layers in a display device according to an embodiment of the present invention.

FIG. 7 is a plan view showing a layout of one or more layers in a display device according to an embodiment of the present invention.

FIG. 8 is a plan view showing a layout of one or more layers in a display device according to an embodiment of the present invention.

FIG. 9 is a plan view showing a layout of one or more layers in a display device according to an embodiment of the present invention.

FIG. 10 is a plan view showing a layout of one or more layers in a display device according to an embodiment of the present invention.

FIG. 11 is a plan view showing a layout of one or more layers in a display device according to an embodiment of the present invention.

FIG. 12 is a plan view showing a layout of one or more layers in a display device according to an embodiment of the present invention.

FIG. 13 is a plan view showing a layout of one or more layers in a display device according to an embodiment of the present invention.

FIG. 14 is a cross-sectional view showing crystallizability of a transparent conductive layer in a semiconductor device according to an embodiment of the present invention

FIG. 15 is a plan view showing an outline of a display device according to an embodiment of the present invention.

FIG. 16 is a block diagram showing a circuit configuration of a display device according to an embodiment of the present invention.

FIG. 17 is a circuit diagram showing a pixel circuit of a display device according to an embodiment of the present invention.

FIG. 18 is a diagram showing electrical characteristics of a semiconductor device according to an embodiment of the present invention.

FIG. 19 is a diagram showing contact resistance values of an oxide semiconductor layer and a transparent conductive layer in a semiconductor device according to an embodiment of the present invention.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention.

For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the embodiments of the present invention, a direction from a substrate to an oxide semiconductor layer is referred to as upper or above. On the contrary, a direction from the oxide semiconductor layer to the substrate is referred to as lower or below. As described above, for convenience of explanation, although the phrase “above” or “below” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer as the display device, the structure in the present embodiment can be applied to a display device including the other electro-optical layers described above.

The expressions “a includes A, B, or C”, “a includes any of A, B, or C”, and “a includes one selected from a group consisting of A, B, and C” do not exclude the case where a includes multiple combinations of A to C unless otherwise specified. Furthermore, these expressions do not exclude the case where a includes other elements.

The following embodiments may be combined with each other as long as there is no technical contradiction.

An object of one embodiment of the present invention is to increase a process margin without deteriorating electrical characteristics of a semiconductor device.

### 1. First Embodiment

### [1-1. Configuration of Display Device 10]

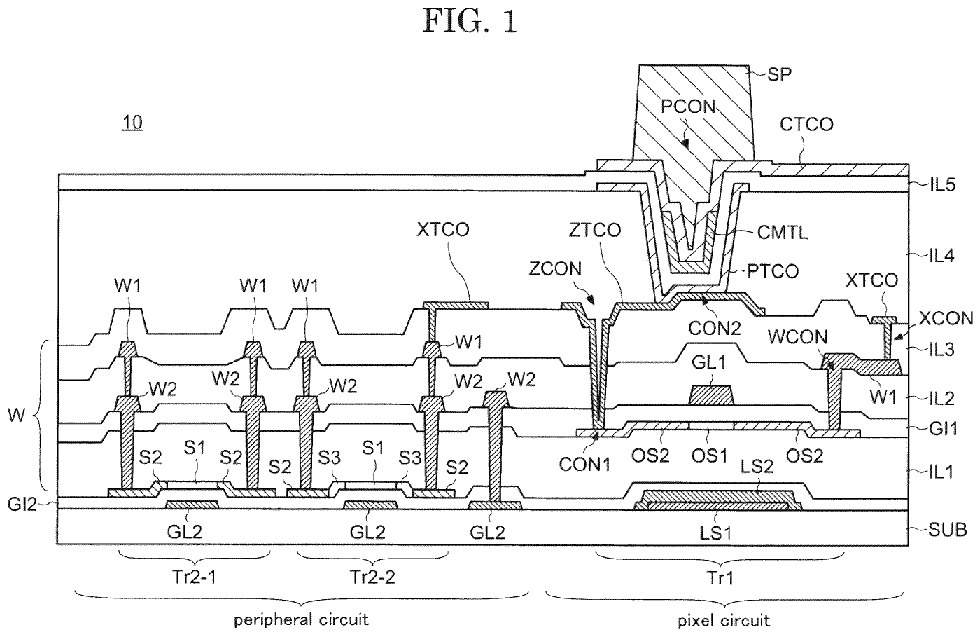

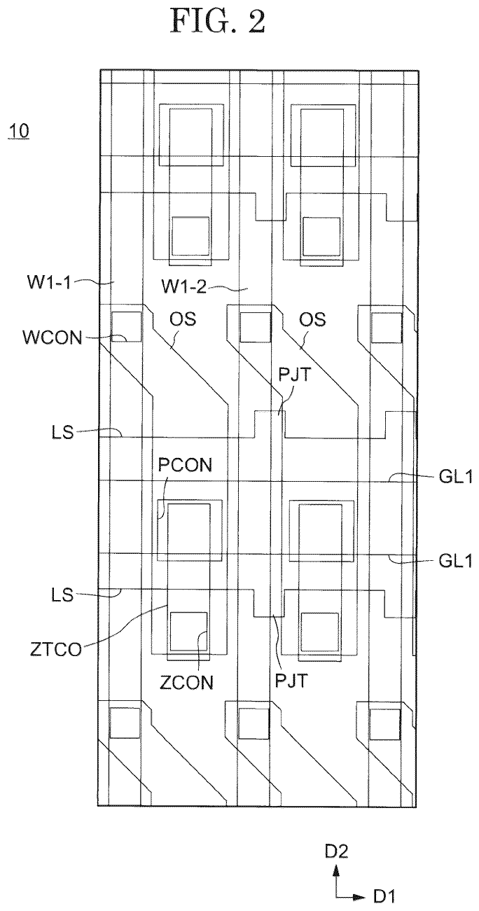

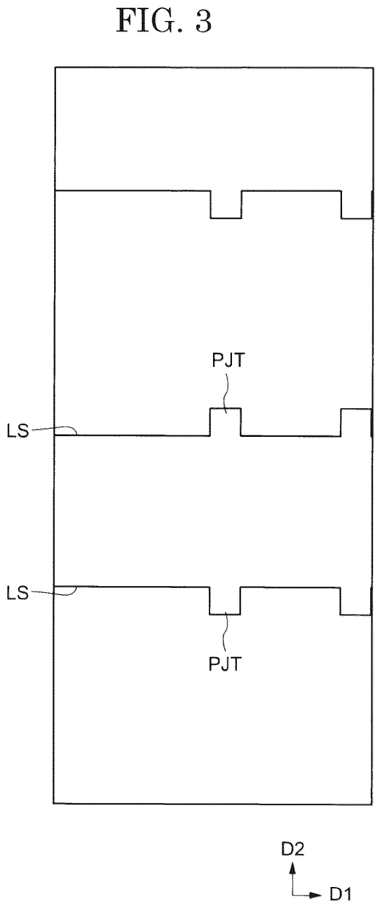

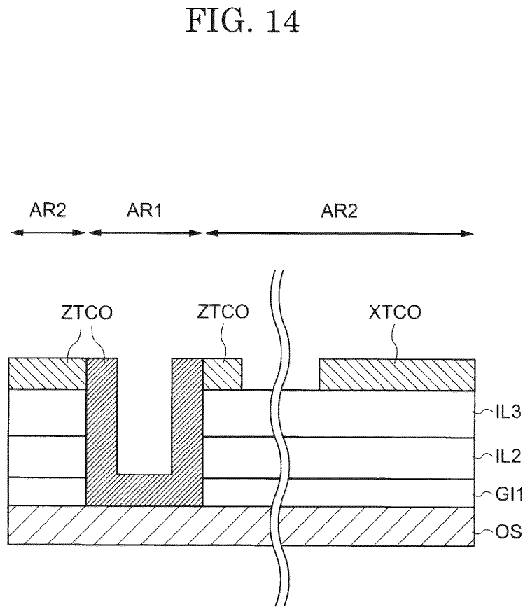

A configuration of a display device 10 according to an embodiment of the present invention will be described with reference to FIG. 1 to FIG. 14. FIG. 1 is a cross-sectional view showing an outline of a display device according to an embodiment of the present invention. FIG. 2 is a plan view showing an outline of a display device according to an embodiment of the present invention. FIG. 3 to FIG. 13 are plan views showing layouts of each layer in a display device according to an embodiment of the present invention. FIG. 14 is a cross-sectional view showing crystallizability of a transparent conductive layer in a semiconductor device according to an embodiment of the present invention. The cross-sectional view in FIG. 1 is for explaining a layer structure of the display device 10, which may not exactly match the plan view in FIG. 2.

As shown in FIG. 1, the display device 10 includes a substrate SUB. The display device 10 also includes a transistor Tr1, a transistor Tr2, a wiring W, a pixel electrode PTCO, a common auxiliary electrode CMTL, and a common electrode CTCO on the substrate SUB. TCO is an abbreviation for Transparent Conductive Oxide. The transistor Tr1 is a semiconductor device included in a pixel circuit of the display device 10. The transistor Tr2 is a semiconductor device included in a peripheral circuit. As will be described in detail later, the peripheral circuit is a circuit configured to drive the pixel circuit. In the following explanation, “semiconductor device” may include only a configuration of the transistor Tr1, and may include both configurations of the transistor Tr1 and Tr2.

### [1-2. Configuration of Transistor Tr1]

The transistor Tr1 includes an oxide semiconductor layer OS (OS1 and OS2), a gate insulating layer GI1, a gate electrode GL1, a connecting electrode ZTCO and a wiring XTCO. The gate electrode GL1 faces the oxide semiconductor layer OS. The gate insulating layer GI1 is provided between the oxide semiconductor layer OS and the gate electrode GL1. In the present embodiment, although a top gate type transistor in which the oxide semiconductor layer OS is provided closer to the substrate SUB than the gate electrode GL1 is exemplified, a bottom gate type transistor in which a positional relationship between the gate electrode GL1 and the oxide semiconductor layer OS is reversed may be applied.

The oxide semiconductor layer OS includes a polycrystalline structure. The oxide semiconductor layer OS includes oxide semiconductor layers OS1, OS2. The oxide semiconductor layer OS1 is an oxide semiconductor layer in a region overlapping the gate electrode GL1 in a plan view. The oxide semiconductor layer OS1 functions as a semiconductor layer and is switched between a conductive state and a non-conductive state according to a voltage supplied to the gate electrode GL1. That is, the oxide semiconductor layer OS1 functions as a channel for the transistor Tr1. The oxide semiconductor layer OS2 functions as a conductive layer. The oxide semiconductor layers OS1, OS2 are layers formed from the same oxide semiconductor layer. For example, the oxide semiconductor layer OS2 is a low resistance oxide semiconductor layer formed by implanting impurities into a layer which has the same physical properties as the oxide semiconductor layer OS1.

An insulating layer IL2 is provided above the gate electrode GL1. A wiring W1 is provided above the insulating layer IL2. The wiring W1 is connected to the oxide semiconductor layer OS2 via an opening WCON provided in the insulating layer IL2 and the gate insulating layer GI1. The wiring W1 is a metal layer. A data signal related to pixel gradation is transmitted to the wiring W1. An insulating layer IL3 is provided above the insulating layer IL2 and the wiring W1. The connecting electrode ZTCO and the wiring XTCO are in contact with an upper surface of the insulating layer IL3 above the insulating layer IL3. In other words, the insulating layers IL3 are in contact with lower surfaces of the connecting electrodes ZTCO and the wiring XTCO below the connecting electrodes ZTCO and the wiring XTCO.

The connecting electrode ZTCO is connected to the oxide semiconductor layer OS2 via an opening ZCON provided in the gate insulating layer GI1 and the insulating layers IL3 and IL2. The connecting electrode ZTCO is in contact with the oxide semiconductor layer OS2 at a bottom portion of the opening ZCON. The wiring XTCO is connected to the wiring W1 via an opening XCON provided in the insulating layers IL3. The connecting electrode ZTCO and the wiring XTCO are transparent conductive layers. As described above, the gate electrode GL1, the connecting electrode ZTCO, and the wiring XTCO are provided above the oxide semiconductor layers OS.

The connecting electrode ZTCO may be referred to as a “first transparent conductive layer”. The wiring XTCO may be referred to as a “second transparent conductive layer.” The wiring XTCO is provided in the same layer as the connecting electrode ZTCO and is separated from the connecting electrode ZTCO. Although materials of the connecting electrode ZTCO is the same as materials of the wiring XTCO, crystallizability of a portion of the connecting electrode ZTCO is different from crystallizability of the wiring XTCO. For example, even if the connecting electrode ZTCO and the wiring XTCO are both formed by the same process, crystallizability of a portion of ITO used as the connecting electrode ZTCO is different from crystallizability of ITO used as the wiring XTCO. Different crystallizabilities include different crystal structures, different parameters such as lattice constants even if the crystal structures are the same, and the like. When transparent conductive layers having different crystallizability are observed with an optical microscope, these transparent conductive layers are observed in different colors. That is, refractive indices of these transparent conductive layers are different.

The insulating layer IL2 may be referred to as a “first insulating layer”. The insulating layer IL3 may be referred to as a “second insulating layer”. The opening WCON may be referred to as a “first opening”. The opening ZCON may be referred to as a “second opening”. As described above, the insulating layer IL2 is provided above the oxide semiconductor layer OS and the gate electrode GL1.

As will be described later, the connecting electrode ZTCO is divided into a first region and a second region in a plan view. The first region includes a region in which the connecting electrode ZTCO is in contact with the oxide semiconductor layer OS. The second region is a region other than the first region. Crystallizability of the connecting electrode ZTCO in the first region is different from crystallizability of the connecting electrode ZTCO in the second region.

For example, when a transparent conductive layer such as an ITO layer is formed in contact with a semiconductor layer such as a silicon layer, a surface of the semiconductor layer is oxidized by a process gas or oxygen ions at the time of a deposition of an ITO film. Since an oxide layer formed on the surface of the semiconductor layer is high resistance, a contact resistance between the semiconductor layer and the transparent conductive layer is increased. As a result, there is a defect in an electrical contact between the semiconductor layer and the transparent conductive layer.

On the other hand, a high resistance oxide layer as described above is not formed on the oxide semiconductor layer OS in the case where the connecting electrode ZTCO is formed so as to be in contact with the oxide semiconductor layer OS including the polycrystalline structure.

The above reason is presumed as follows. When the connecting electrode ZTCO is formed so as to be in contact with the oxide semiconductor layer OS as described above, the connecting electrode ZTCO formed above the oxide semiconductor layer OS is crystallized immediately after the film is formed, reflecting an crystal structure of the oxide semiconductor layer OS. For example, in the case where the connecting electrode ZTCO is formed under a certain condition of forming the film, although the connecting electrode ZTCO formed at a place other than the oxide semiconductor layer OS is not crystallized, the connecting electrode ZTCO formed at a place in contact with the oxide semiconductor layer OS is crystallized. As described above, crystallization of the connecting electrode ZTCO during film formation is considered to reduce the oxide semiconductor layer OS in the region of the oxide semiconductor layer OS in contact with the connecting electrode ZTCO. Therefore, it is considered that carrier concentration at a surface of the oxide semiconductor layer OS increased, and a contact resistance between the oxide semiconductor layer OS and the connection electrode ZTCO decreased.

An insulating layer IL4 is provided above the connecting electrode ZTCO. The insulating layer IL4 eases (flattens) a step formed from a structure provided below the insulating layer IL4. The insulating layer IL4 may be referred to as a planarization film. The pixel electrode PTCO is provided above the insulating layer IL4. The pixel electrode PTCO is connected to the connecting electrode ZTCO via an opening PCON provided in the insulating layer IL4. A region where the connecting electrode ZTCO and the pixel electrode PTCO are in contact with each other is referred to as a contact region CON2. The contact region CON2 overlaps the gate electrode GL1 in a plan view. The pixel electrode PTCO is a transparent conductive layer.

An insulating layer IL5 is provided above the pixel electrode PTCO. The common auxiliary electrode CMTL and the common electrode CTCO are provided above the insulating layer IL5. That is, the pixel electrode PTCO faces the common electrode CTCO via the insulating layer IL5. The common electrode CTCO is connected to the common auxiliary electrode CMTL at the opening PCON. As will be described in detail later, the common auxiliary electrode CMTL and the common electrode CTCO have different patterns respectively when seen a plan view. The common auxiliary electrode CMTL is a metal layer. The common electrode CTCO is a transparent conductive layer. The electric resistance of the common auxiliary electrode CMTL is lower than the electric resistance of the common electrode CTCO. The common auxiliary electrode CMTL also functions as a light-shielding layer. For example, the common auxiliary electrode CMTL shields light from adjacent pixels to suppress an occurrence of color mixing. A spacer SP is provided above the common electrode CTCO.

The spacer SP is provided for a part of the pixels. For example, the spacer SP may be provided for any one of a blue pixel, a red pixel and a green pixel. However, the spacer SP may be provided for all the pixels. A height of the spacer SP is half the height of a cell gap. A spacer is also provided on a counter substrate, and the spacer on the counter substrate and the above spacer SP overlap in a plan view.

A light-shielding layer LS is provided between the transistor Tr1 and the substrate SUB. In the present embodiment, light-shielding layers LS1, LS2 are provided as the light-shielding layer LS. However, the light-shielding layer LS may be formed of only the light-shielding layer LS1 or LS2. In a plan view, the light-shielding layer LS is provided in a region where the gate electrode GL1 and the oxide semiconductor layer OS overlap. That is, in a plan view, the light-shielding layer LS is provided in a region overlapping the oxide semiconductor layer OS1. The light-shielding layer LS suppresses the light incident from the substrate SUB side from reaching the oxide semiconductor layer OS1. In the case where a conductive layer is used as the light-shielding layer LS, a voltage may be applied to the light-shielding layer LS to control the oxide semiconductor layer OS1. In the case where a voltage is applied to the light-shielding layer LS, the light-shielding layer LS and the gate electrode GL1 may be connected by a peripheral region of the pixel circuit. In a plan view, the above contact region CON1 is provided in a region not overlapping the light-shielding layer LS.

In the present embodiment, although a configuration in which the oxide semiconductor layer OS is in contact with the insulating layer IL1 has been exemplified, the configuration is not limited to this configuration. For example, a metal oxide layer may be provided between the oxide semiconductor layer OS and the insulating layer IL1. For example, a metal oxide containing aluminum as a main component may be used as the metal oxide layer. Specifically, aluminum oxide may be used as the metal oxide layer. Here, the metal oxide layer may be provided in the same region as the insulating layer IL1, or may be processed into the same pattern as the oxide semiconductor layer OS.

### [1-3. Configuration of Transistor Tr2]

The transistor Tr2 has a p-type transistor Tr2-1 and an n-type transistor Tr2-2.

The p-type transistor Tr2-1 and the n-type transistor Tr2-2 both include a gate electrode GL2, a gate insulating layer GI2, and a semiconductor layer S (S1 to S3). The gate electrode GL2 faces the semiconductor layer S. The gate insulating layer GI2 is provided between the semiconductor layer S and the gate electrode GL2. In the present embodiment, although a bottom gate type transistor in which the gate electrode GL2 is provided closer to the substrate SUB than the semiconductor layer S is exemplified, a top gate type transistor in which a positional relationship between the semiconductor layer S and the gate electrode GL2 is reversed may be used as the display device.

The semiconductor layer S of the p-type transistor Tr2-1 includes semiconductor layers S1 and S2. The semiconductor layer S of the n-type transistor Tr2-2 includes the semiconductor layers S1, S2 and S3. The semiconductor layer S1 is a semiconductor layer overlapping the gate electrode GL2 in a plan view. The semiconductor layer S1 functions as a channel for the transistors Tr2-1 and Tr2-2. The semiconductor layer S2 functions as a conductive layer. The semiconductor layer S3 functions as a conductive layer with a higher resistance than the semiconductor layer S2. The semiconductor layer S3 suppresses hot carrier degradation by attenuating hot carriers intruding toward the semiconductor layer S1.

The insulating layer IL1 and the gate insulating layer GI1 are provided on the semiconductor layer S. In the transistor Tr2, the gate insulating layer GI1 simply functions as an interlayer film. A wiring W2 is provided above these insulating layers. The wiring W2 is connected to the semiconductor layer S via an opening provided in the insulating layer IL1 and the gate insulating layer GI1. The insulating layer IL2 is provided on the wiring W2. The wiring W1 is provided on the insulating layer IL2. The wiring W1 is connected to the wiring W2 via an opening provided in the insulating layer IL2. The insulating layer IL3 is provided above the wiring W1. The wiring XTCO is provided above the insulating layers IL3. The wiring XTCO is connected to the wiring W1 through an opening provided in the insulating layers IL3.

The gate electrode GL2 and the light-shielding layer LS2 are the same layer. The wiring W2 and the gate electrode GL1 are the same layer. The same layer means that multiple members are formed from one patterned layer.

### [1-4. Plane Layout of Display Device 10]

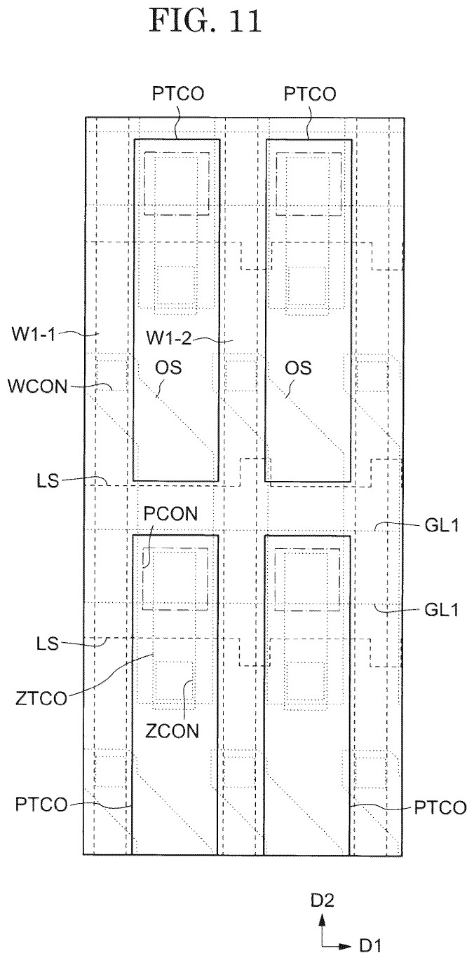

A plane layout of a pixel of the display device 10 will be described with reference to FIG. 2 to FIG. 13. In FIG. 2, the pixel electrode PTCO, the common auxiliary electrode CMTL, the common electrode CTCO, and the spacer SP are omitted. The plane layout of the pixel electrode PTCO, the common auxiliary electrode CMTL, and the common electrode CTCO are shown in FIG. 11 to FIG. 13, respectively.

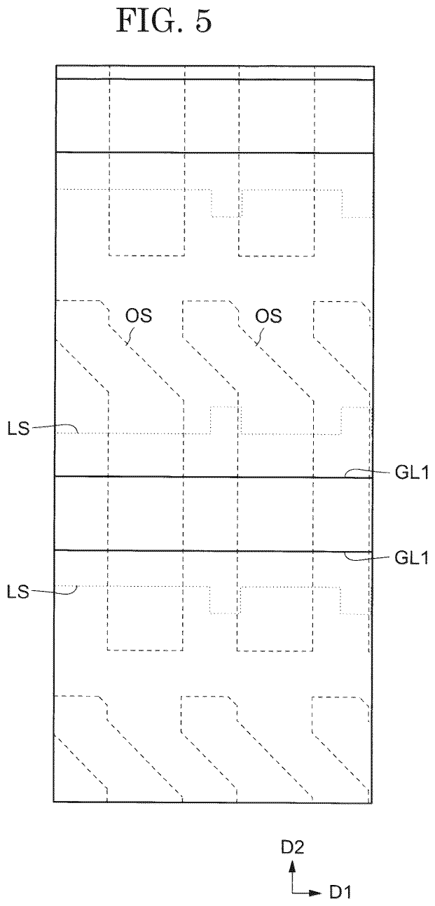

As shown in FIG. 2 and FIG. 3, the light-shielding layer LS extends in a direction D1. A shape of the light-shielding layer LS may be different depending on the pixel. In the present embodiment, a protruding part PJT protruding in a direction D2 is provided from a part of the light-shielding layer LS extending in the direction D1. As shown in FIG. 5, the light-shielding layer LS is provided in a region including the region where the gate electrode GL1 and the oxide semiconductor layer OS overlap in a plan view. The gate electrode GL1 can also be referred to as a “gate line.”

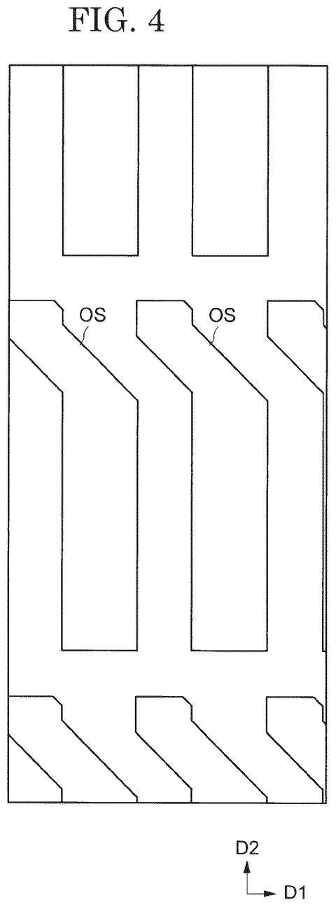

As shown in FIG. 2, FIG. 4, and FIG. 5, the oxide semiconductor layer OS extends in the direction D2. The gate electrode GL1 extends in the direction D1 so as to intersect the oxide semiconductor layer OS. A pattern of the gate electrode GL1 is provided inside a pattern of the light-shielding layer LS. In other words, the oxide semiconductor layers OS is formed in a long shape (a shape having a longitudinal) intersecting the gate electrode GL1.

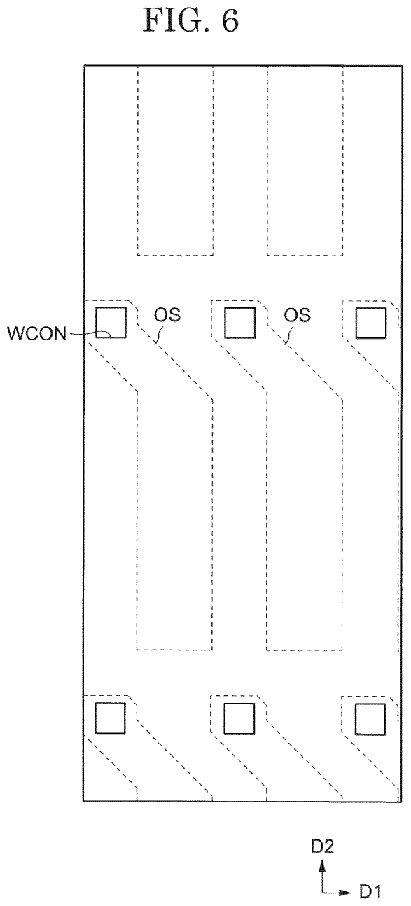

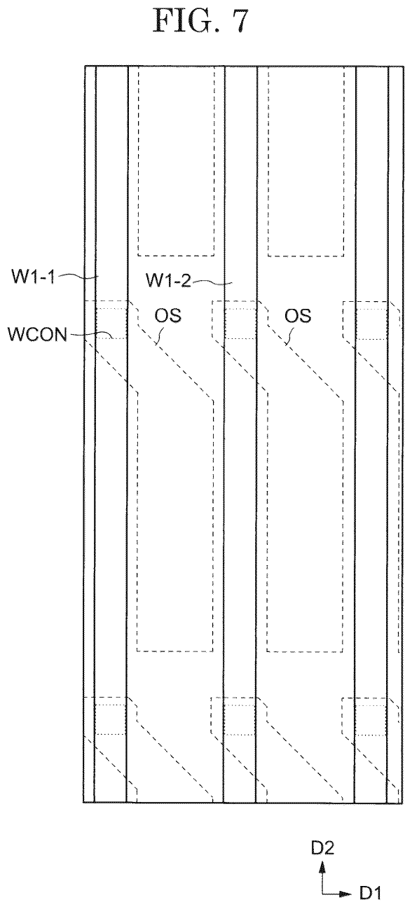

As shown in FIG. 2, FIG. 6, and FIG. 7, the opening WCON is provided in a region overlapping the wiring W1 (W1-1 and W1-2) near an upper end of the pattern of the oxide semiconductor layer OS. A main part of the pattern of the oxide semiconductor layer OS extends in the direction D2 between a pair of the adjacent wirings W1 (W1-1 and W1-2). The remaining part of the pattern of the oxide semiconductor layer OS extends obliquely in the direction D1 and the direction D2 from the main part and overlaps the opening WCON.

As shown in FIG. 2 and FIG. 7, multiple wirings W1 extend in the direction D2. In the case where the adjacent wirings W1 need to be described separately, the adjacent wiring W1 is referred to as a wiring W1-1 and a wiring W1-2. In this case, it can be said that the main part of the oxide semiconductor layer OS extends in the direction D2 between the wiring W1-1 and the wiring W1-2, and intersects the gate electrode GL1. In other words, the oxide semiconductor layer OS is provided in a long shape in the direction D2 and connected to the wiring W1-1 at one end in a longitudinal direction of the oxide semiconductor layer OS.

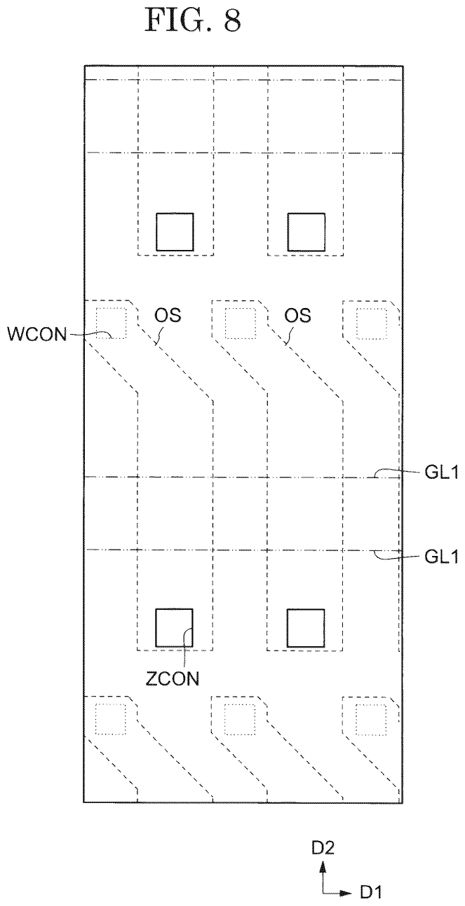

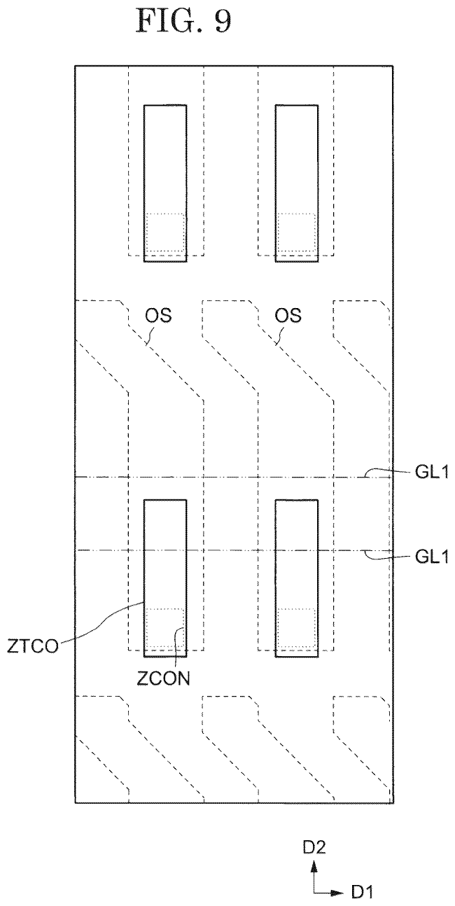

As shown in FIG. 2, FIG. 8, and FIG. 9, the opening ZCON is provided near a lower end of the pattern of the oxide semiconductor layer OS. The opening ZCON is provided in a region overlapping the pattern of the oxide semiconductor layer OS and not overlapping the gate electrode GL1. The opening ZCON is provided in a region overlapping the connecting electrode ZTCO. The connecting electrode ZTCO overlaps the gate electrode GL1 and the oxide semiconductor layer OS between the wiring W1-1 and the wiring W1-2. Therefore, the connecting electrode ZTCO is in contact with the oxide semiconductor layer OS in the opening ZCON not overlapping the gate electrode GL1.

In other words, the oxide semiconductor layer OS is connected to the connecting electrode ZTCO at the other end in the longitudinal direction of the oxide semiconductor layer OS. The connecting electrode ZTCO is formed in a long shape extending in the direction D2 similar to the oxide semiconductor layer OS. In the direction D1, a width of the connecting electrode ZTCO is smaller than a width of the oxide semiconductor layer OS.

As shown in FIG. 2, FIG. 7, and FIG. 8, the oxide semiconductor layer OS is in contact with the wiring W1 at the opposite side of the opening ZCON with respect to the gate electrode GL1. The opening ZCON does not overlap with the light-shielding layer LS.

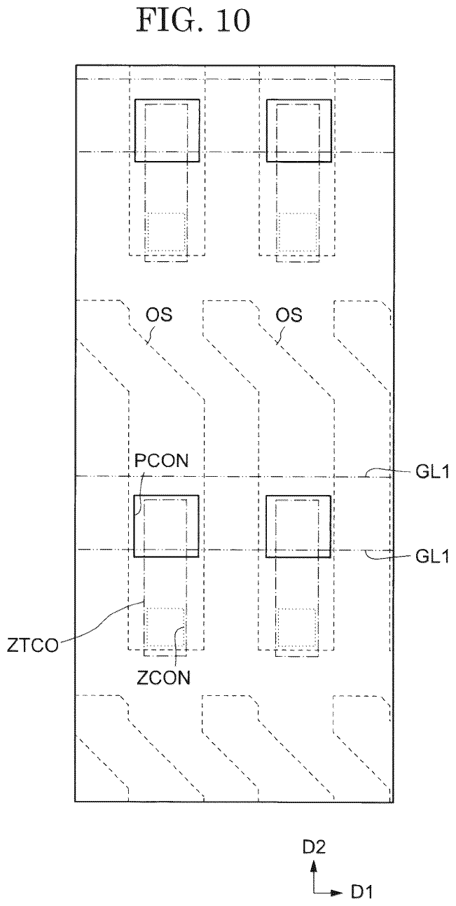

As shown in FIG. 2, FIG. 10, and FIG. 11, the opening PCON is provided near an upper end of a pattern of the connecting electrode ZTCO. The opening PCON is provided in a region overlapping the pattern of the gate electrode GL1 and the pattern of the connecting electrode ZTCO. The opening PCON is provided in a region overlapping the pixel electrode PTCO. The pixel electrode PTCO overlaps the gate electrode GL1, the oxide semiconductor layer OS, and the connecting electrode ZTCO between the wiring W1-1 and the wiring W1-2. Therefore, the pixel electrode PTCO is in contact with the connecting electrode ZTCO in the opening PCON overlapping the gate electrode GL1.

The pixel electrode PTCO extends in a translucent region as described below. In other words, the pixel electrode PTCO is formed in a long shape extending in the direction D2 similar to the oxide semiconductor layer OS and the wiring W1-1. In the direction D1, a width of the pixel electrode PTCO is larger than the width of the oxide semiconductor layer OS at a part where the opening PCON is provided.

As shown in FIG. 11, the connecting electrode ZTCO is formed in a long shape extending along the wiring W1-1. In the direction D1, a width of the opening PCON constituting the contact region CON2 is larger than the width of the connecting electrode ZTCO. The connecting electrode ZTCO entirely overlaps the pixel electrode PTCO in a plan view.

As shown in FIG. 11, the pixel electrodes PTCO are aligned in the direction D2. Of the pixels adjacent to the direction D2, one pixel may be referred to as a “first pixel”, and the other pixel may be referred to as a “second pixel”. For example, the first pixel is a pixel corresponding to the upper pixel electrode PTCO among the pixel electrodes PTCO aligned in the direction D2 in FIG. 11, and the second pixel is a pixel corresponding to the lower pixel electrode PTCO among the pixel electrodes PTCO aligned in the direction D2 in FIG. 11. In this case, the first pixel and the second pixel are supplied with a pixel signal from the wiring W1-1.

The pixel electrodes PTCO are aligned in the direction D1. A pixel adjacent in the direction D1 with respect to the above first pixel is referred to as a “third pixel”, and a pixel adjacent in the direction D1 with respect to the second pixel is referred to as a “fourth pixel”. The third pixel and the fourth pixel are adjacent to each other in the direction D2. The third pixel and the fourth pixel are supplied with the pixel signal from the wiring W1-2 adjacent to the wiring W1-1.

As described above, each of the first pixel, the second pixel, the third pixel, and the fourth pixel includes the transistor Tr1 (pixel transistor), the connecting electrode ZTCO, and the pixel electrode PTCO.

The transistor Tr1 includes the oxide semiconductor layer OS, the gate electrode GL1 facing the oxide semiconductor layer OS, and the gate insulating layer GI1 between the oxide semiconductor layer OS and the gate electrode GL1. The connecting electrode ZTCO overlaps the gate electrode GL1 and the oxide semiconductor layer OS and contacts the oxide semiconductor layer OS in the opening ZCON not overlapped with the gate electrode GL1 in a plan view. The pixel electrode PTCO overlaps the gate electrode GL1, the oxide semiconductor layer OS, and the connecting electrode ZTCO and is connected to the connecting electrode ZTCO in the opening PCON overlapping the gate electrode GL1 in a plan view.

The pixel electrode PTCO of the first pixel provided on the upper side in FIG. 11 overlaps the oxide semiconductor layer OS of the first pixel and the oxide semiconductor layer OS of the second pixel provided on the lower side of the first pixel in a plan view. Further, the pixel electrode PTCO of the first pixel also overlaps a part of the oxide semiconductor layer OS of the fourth pixel in a plan view.

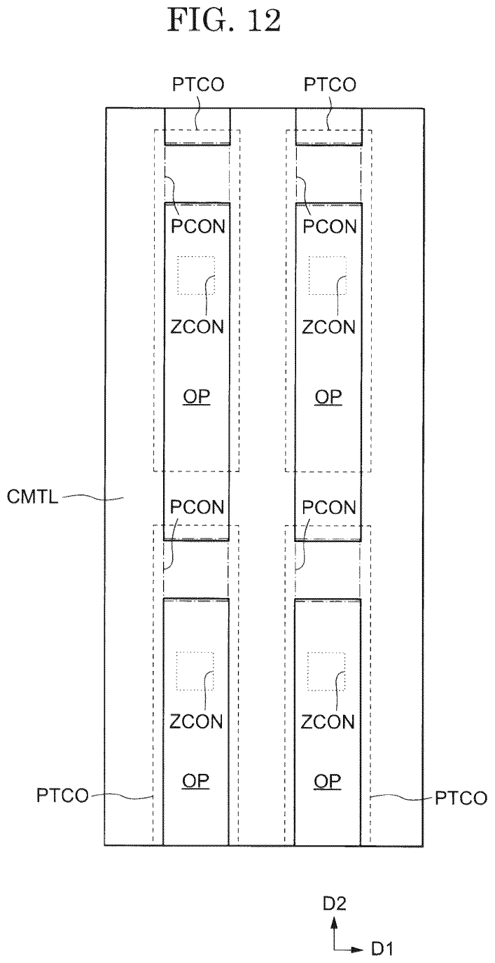

As shown in FIG. 12, the common auxiliary electrode CMTL is provided in a grid shape so as to surround the periphery of a pixel region. That is, the common auxiliary electrode CMTL is provided commonly for multiple pixels. In other words, the common auxiliary electrode CMTL has an opening OP. The opening OP is provided to expose the pixel electrode PTCO. A pattern of the opening OP is provided inside the pattern of the pixel electrode PTCO. A region provided with the opening OP corresponds to a display region. That is, the opening ZCON is included in the display region. The display region means a region in which a user can see light from a pixel. For example, a frame region that is shielded by a metal layer and unperceivable to the user is not included in the display region. That is, the above display region may be referred to as a “translucent region (or opening region)”.

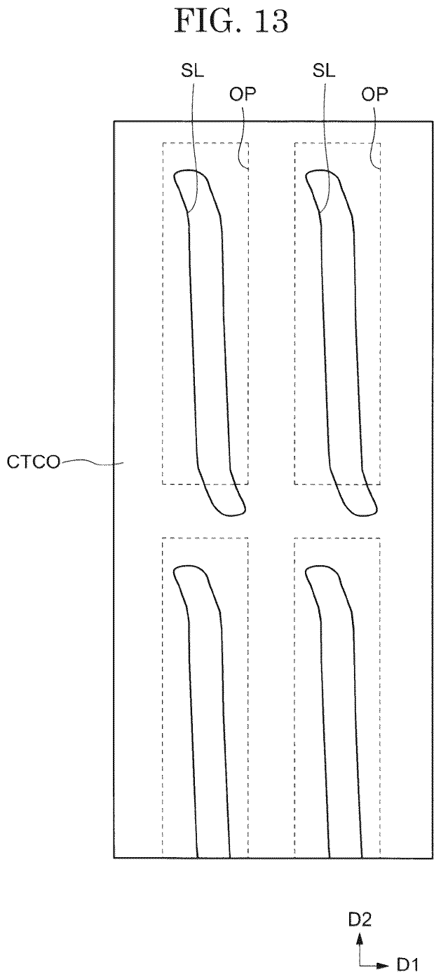

As shown in FIG. 13, the common electrode CTCO is provided commonly for multiple pixels. A slit SL is provided in a region corresponding to the above opening OP. The slit SL has a curved shape (longitudinally long S-shape). A tip of the slit SL has a shape in which a width orthogonal to an extending direction of the tip is reduced. Referring to FIG. 1 and FIG. 13, the common electrode CTCO has the slit SL at a position facing the pixel electrode PTCO.

### [1-5. Crystallizabilities of Connecting Electrode ZTCO and Wiring XTCO]

Crystallizabilities of the connecting electrode ZTCO and the wiring XTCO will be described with reference to FIG. 14. FIG. 14 is an enlarged cross-sectional view of a portion of the transistor Tr1 shown in FIG. 1. In FIG. 14, the connecting electrode ZTCO is represented by two types of hatching. Different hatching means different crystallizability. FIG. 14 is divided into a first region AR1 and a second region AR2. The first region AR1 includes a region in which the connecting electrode ZTCO is connected to the oxide semiconductor layer OS in a plan view. The second region AR2 is a region that is different from the first region AR1. The first region AR1 may refer to only a region in which the connecting electrode ZTCO is connected to the oxide semiconductor layer OS in a plan view, or may refer to a region extending outward from the region.

As shown in FIG. 14, the connecting electrode ZTCO has crystallizability that varies depending on regions. Specifically, the crystallizability of the connecting electrode ZTCO in the first region AR1 is different from the crystallizability of the connecting electrode ZTCO in the second region AR2. The crystallizability of the connecting electrode ZTCO in the second region AR2 is the same as the crystallizability of the wiring XTCO.

In the case where a transparent conductive layer such as ITO is used as the connecting electrode ZTCO and the wiring XTCO, the transparent conductive layer is patterned after being deposited on an entire surface of a substrate, and thus the transparent conductive layer is formed without crystallization. Even if the transparent conductive layer is formed under such conditions, since the oxide semiconductor layer OS is polycrystalline, the transparent conductive layer in the region in contact with the oxide semiconductor layer OS is crystallized immediately after the formation of the transparent conductive layer, reflecting a crystal structure of the oxide semiconductor layer OS. Consequently, in a state immediately after the transparent conductive layer is formed, the transparent conductive layer in the first region AR1 is in a crystalline state, and the transparent conductive layer in the second region AR2 is in an amorphous state.

As described above, after the oxide semiconductor layer OS is patterned, the transparent conductive layer is crystallized by heat treatment in order to reduce resistivity of the transparent conductive layer. This crystallization changes the connecting electrode ZTCO and the wiring XTCO in the second region AR2 from an amorphous state to a crystalline state. On the other hand, since the connecting electrode ZTCO in the first region AR1 is already in a crystalline state, the crystalline state does not change before and after the heat treatment.

As described above, the connecting electrode ZTCO in the first region AR1 is crystallized by reflecting the crystal structure of the oxide semiconductor layer OS, while the connecting electrode ZTCO and the wiring XTCO in the second region are crystallized by heat treatment. Therefore, as shown in FIG. 14, the crystallizability of the connecting electrode ZTCO in the first region AR1 is different from the crystallizability of each of the connecting electrode ZTCO and the wiring XTCO in the second region AR2. The pattern of the connecting electrode ZTCO is a pattern formed by patterning the same transparent conductive layer. Therefore, the connecting electrode ZTCO in the first region AR1 and the connecting electrode ZTCO in the second region AR2 are consecutive.

### [1-6. Materials of Each Member of Display Device 10]

A rigid substrate having light transmittance and no flexibility, such as a glass substrate, a silica substrate, and a sapphire substrate can be used as the substrate SUB. On the other hand, in the case where the substrate SUB needs to have a flexibility, a flexible substrate containing a resin and having flexibility, such as a polyimide substrate, an acrylic substrate, a siloxane substrate, or a fluororesin substrate can be used as the substrate SUB. In order to improve the heat resistance of the substrate SUB, impurities may be introduced into the above resin.

General metal materials can be used as the gate electrodes GL1, GL2, the wirings W1, W2, the light-shielding layer LS, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), and silver (Ag), or alloys or compounds thereof are used as members of these electrodes and the like. The above materials may be used in a single layer or a stacked layer as the members of the above electrodes and the like.

For example, a stacked structure of Ti/Al/Ti is used as the gate electrode GL1. In the present embodiment, the cross-sectional shape of a pattern end of the gate electrode GL1 having the above stacked structure is a forward taper shape.

General insulating materials can be used as the gate insulating layers GI1, GI2 and the insulating layers IL1 to IL5. For example, inorganic insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), and the like can be used as the gate insulating layers GI1, GI2 and the insulating layers IL1 to IL3, and IL5. Low-defect insulating layers can be used as these insulating layers. Organic insulating materials such as a polyimide resin, an acrylic resin, an epoxy resin, a silicone resin, a fluororesin, or a siloxane resin can be used as the insulating layer IL4. The above organic insulating materials may be used as the gate insulating layers GI1, GI2, and the insulating layers IL1 to IL3, IL5. The above materials may be used in a single layer or a stacked layer as a member of the insulating layer and the like.

SiOₓ with a thickness of 100 nm is used as the gate insulating layer GI1 as an example of the above insulating layer. SiOₓ/SiNₓ/SiOₓ with a total thickness of 300 nm to 700 nm is used as the insulating layer IL1. SiOₓ/SiNₓ with a total thickness of 60 nm to 150 nm is used as the gate insulating layer GI2. SiOₓ/SiNₓ/SiOₓ with a total thickness of 300 nm to 500 nm is used as the insulating layer IL2. SiOₓ (single layer), SiNₓ (single layer) or a stacked layer thereof with a total thickness of 200 nm to 500 nm is used as the insulating layer IL3. The organic layer with a thickness of 2 μm to 4 μm is used as the insulating layer IL4. SiNₓ (single layer) with a thickness of 50 nm to 150 nm is used as the insulating layer IL5.

The above SiOₓN_{y} and AlOₓN_{y} are silicone compounds and aluminum compounds containing nitrogen (N) in a smaller ratio (x>y) than oxygen (O). The above SiNₓO_{y} and AlNₓO_{y} are silicon compounds and aluminum compounds containing oxygen in a smaller ratio (x>y) than nitrogen.

A metal oxide having semiconductor characteristics can be used as the oxide semiconductor layer OS. For example, an oxide semiconductor containing indium (In), gallium (Ga), zinc (Zn), and oxygen (O) can be used as the oxide semiconductor layer OS. For example, an oxide semiconductor having a composition ratio of In:Ga:Zn:O=1:1:1:4 can be used as the oxide semiconductor layer OS. However, the oxide semiconductor containing In, Ga, Zn, and O used in the present embodiment is not limited to the above composition, and an oxide semiconductor having a composition different from that described above can also be used. For example, an oxide semiconductor layer that the ratio of In is larger than that described above may be used to improve mobility. On the other hand, an oxide semiconductor layer that the ratio of Ga is larger than that described above may be used to increase the band gap and reduce the influence of light irradiation.

For example, an oxide semiconductor containing two or more metals containing indium (In) may be used as the oxide semiconductor layer OS having an In ratio higher than that described above. In this case, in the oxide semiconductor layer OS, a ratio of an indium element to a total metal element may be 50% or more in atomic ratio. As the oxide semiconductor layer OS, in addition to indium, gallium (Ga), zinc (Zn), aluminum (Al), hafnium (Hf), yttrium (Y), zirconia (Zr), and lanthanoids may be used. An element other than the above may be used as the oxide semiconductor layer OS.

As the oxide semiconductor layer OS, other elements may be added to the oxide semiconductor containing In, Ga, Zn, and O. For example, a metallic element such as Al, Sn may be added to the oxide semiconductor. In addition to the oxide semiconductor described above, an oxide semiconductor containing In and Ga (IGO), an oxide semiconductor containing In and Zn (IZO), an oxide semiconductor containing In, Sn and Zn (ITZO), an oxide semiconductor containing In and W, and the like may be used as the oxide semiconductor layer OS.

In the case where the ratio of the indium element in the oxide semiconductor layer OS is large, the oxide semiconductor layer OS is likely to crystallize. As described above, in the oxide semiconductor layer OS, the oxide semiconductor layer OS having a polycrystalline structure can be obtained by using a material in which a ratio of the indium element to a total metal element is 50% or more. As the metal element other than indium, gallium is preferably contained. Gallium belongs to the same Group 13 element as indium.

Therefore, since the crystallizability of the oxide semiconductor layer OS is not inhibited by gallium, the oxide semiconductor layer OS is polycrystalline.

Although a detailed method for manufacturing the oxide semiconductor layer OS will be described later, the oxide semiconductor layer OS can be formed using a sputtering method. A composition of the oxide semiconductor layer OS formed by the sputtering method depends on a composition of a sputtering target. Even if the oxide semiconductor layer OS has a polycrystalline structure, the composition of the sputtering target substantially matches the composition of the oxide semiconductor layer OS. In this case, a composition of a metal element in the oxide semiconductor layer OS can be specified based on a composition of a metal element of the sputtering target.

In the case where the oxide semiconductor layer OS has a polycrystalline structure, the composition of the oxide semiconductor layer may be specified using an X-ray diffractometry (X-ray Diffraction: XRD) method. Specifically, the composition of the metallic element of the oxide semiconductor layer can be specified based on a crystal structure and a lattice constant of the oxide semiconductor layer obtained by XRD method. In addition, the composition of the metallic element in the oxide semiconductor layer OS can also be determined by fluorescent X-ray analysis or electron probe micro analyzer (Electron Probe Micro Analyzer: EPMA) analysis. However, the oxygen element contained in the oxide semiconductor layer OS is not limited to this because the oxygen element varies depending on the sputtering process conditions.

As described above, the oxide semiconductor layer OS has the polycrystalline structure. The oxide semiconductor having the polycrystalline structure can be manufactured using Poly-OS (Poly-crystalline Oxide Semiconductor) techniques. Hereinafter, when distinguishing from an oxide semiconductor having an amorphous structure, the oxide semiconductor having the polycrystalline structure is sometimes described as an Poly-OS.

A transparent conductive layer is used as the connecting electrode ZTCO, the wiring XTCO, the pixel electrode PTCO, and the common electrode CTCO as described above. A mixture of ITO and a mixture of indium oxide and zinc oxide (IZO) can be used as the transparent conductive layer. Materials other than the above may be used as the transparent conductive layer.

As described above, in the case where a metal oxide layer is arranged between the oxide semiconductor layer OS and the insulating layer IL1, a metal oxide containing aluminum as the main component is used as the metal oxide layer. For example, an inorganic insulating layer such as aluminum oxide (AlOₓ), aluminum oxynitride (AlOₓN_{y}), aluminum nitride oxide (AlNₓO_{y}), and aluminum nitride (AlNₓ) is used as the metal oxide layer. The “metal oxide layer containing aluminum as the main component” means that the ratio of aluminum contained in the metal oxide layer is 1% or more of the total amount of the metal oxide layer. The ratio of aluminum contained in the metal oxide layer may be 5% or more and 70% or less, 10% or more and 60% or less, or 30% or more and 50% or less of the total amount of the metal oxide layer. The ratio may be a mass ratio or a weight ratio.

As described above, according to the transistor Tr1 of the present embodiment, conduction between the oxide semiconductor layer OS including the polycrystalline structure and the connecting electrode ZTCO as the transparent conductive layer can be ensured. Therefore, there is no need to provide a metallic layer between the oxide semiconductor layer OS and the connecting electrode ZTCO. Further, although the detail description will be described later, the transistor Tr1 according to the present embodiment can reduce contact resistivity between the oxide semiconductor layers OS and the connecting electrode ZTCO. Therefore, process margin can be increased without deteriorating electric properties of the transistor Tr1.

In accordance with this configuration, since light is not blocked in the opening ZCON, it is possible to suppress a decrease in an aperture ratio. The oxide semiconductor layer has a light-transmitting property. Therefore, in the present embodiment, although the oxide semiconductor layer is provided in an opening region of the pixel region, light from a backlight passes through the oxide semiconductor layer. Therefore, a decrease in transmittance of the opening region due to the oxide semiconductor layer being provided in the opening region is suppressed. Since the oxide semiconductor layer OS has the light-transmitting property, the oxide semiconductor layer OS is unlikely to cause unevenness in transmitted light unlike the silicon layer. Since the oxide semiconductor layer OS is provided in the display region, generation of display unevenness can be suppressed.

### 2. Second Embodiment

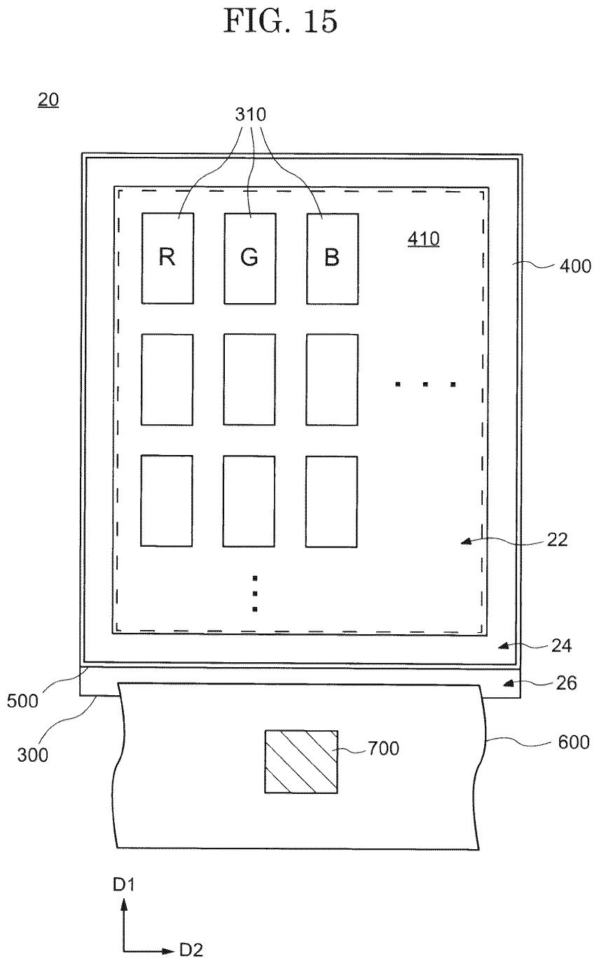

An entire configuration of the display device described in the first embodiment will be described with reference to FIG. 15 to FIG. 17.

### [2-1. Outline of Display Device 20]

FIG. 15 is a plan view showing an outline of a display device according to an embodiment of the present invention. As shown in FIG. 15, a display device includes an array substrate 300, a seal part 400, a counter substrate 500, a flexible printed circuit board 600 (FPC 600), and an IC chip 700. The array substrate 300 and the counter substrate 500 are bonded by the seal part 400. Multiple pixel circuits 310 are arranged in a matrix in a liquid crystal region 22 surrounded by the seal part 400. The liquid crystal region 22 is a region overlapping a liquid crystal element 410 described later in a plan view. The liquid crystal region 22 is a region configured to contribute to display. The liquid crystal region 22 may be referred to as a “display region”. The transistor Tr1 is provided in the liquid crystal region 22 (display region).

A seal region 24 provided with the seal part 400 is a region around the liquid crystal region 22. The FPC 600 is provided in a terminal region 26. The terminal region 26 is a region where the array substrate 300 is exposed from the counter substrate 500 and provided outside the seal region 24. The exterior side of the seal region means outside the region provided with the seal part 400 and outside the region surrounded by the seal part 400. The IC chip 700 is provided on the FPC 600. The IC chip 700 supplies a signal for driving each pixel circuit 310. The seal region 24 or a region combined with the seal region 24 and the terminal region 26 is a region that surrounds the liquid crystal region 22 (display region). These regions may be referred to as a “frame region”. The transistor Tr2 is provided in the frame region.

### [2-2. Circuit Configuration of Display Device 20]

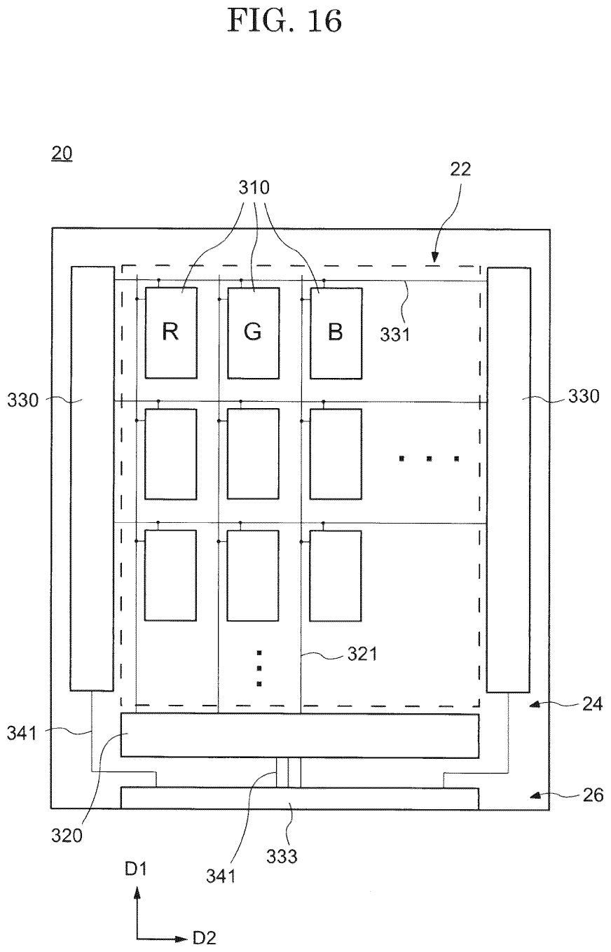

FIG. 16 is a block diagram showing a circuit configuration of a display device according to an embodiment of the present invention. As shown in FIG. 16, a source driver circuit 320 and the liquid crystal region 22 where the pixel circuit 310 is arranged are adjacent in the direction D1 (column direction), and the gate driver circuit 330 and the liquid crystal region 22 are adjacent in the direction D2 (row direction). The source driver circuit 320 and the gate driver circuit 330 are provided in the seal region 24 described above. However, the region where the source driver circuit 320 and the gate driver circuit 330 are provided is not limited to the seal region 24, and it may be any region as long as it is the outside the region provided with the pixel circuit 310.

A source wiring 321 extends in the direction D1 from the source driver circuit 320 and is connected to the multiple pixel circuits 310 arranged in the direction D1. A gate wiring 331 extends in the direction D2 from the gate driver circuit 330 and is connected to the multiple pixel circuits 310 arranged in the direction D2.

The terminal region 26 is provided with a terminal part 333. The terminal part 333 and the source driver circuit 320 are connected by a connecting wiring 341. Similarly, the terminal part 333 and the gate driver circuit 330 are connected by the connecting wiring 341. When the FPC 600 is connected to the terminal part 333, an external device to which the FPC 600 is connected and the display device 20 are connected, and each pixel circuit 310 provided in the display device is driven by a signal from the external device.

The transistor Tr1 shown in the first embodiment is used for the pixel circuit 310. The transistor Tr2 shown in the first embodiment and the second embodiment is applied to the transistor included in the source driver circuit 320 and the gate driver circuit 330.

### [2-3. Pixel Circuit 310 of Display Device 20]

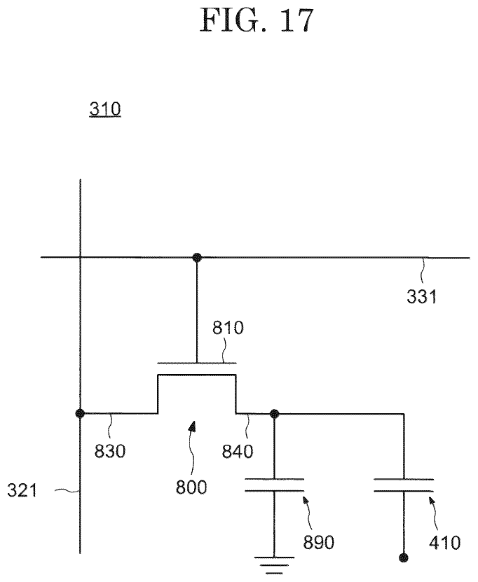

FIG. 17 is a circuit diagram showing a pixel circuit of a display device according to an embodiment of the present invention. As shown in FIG. 17, the pixel circuit 310 includes elements such as a transistor 800, a storage capacitor 890, and the liquid crystal element 410. One electrode of the storage capacitor 890 is the pixel electrode PTCO and the other electrode is the common electrode CTCO. Similarly, one electrode of the liquid crystal element 410 is the pixel electrode PTCO and the other electrode is the common electrode CTCO. The transistor 800 includes a first gate electrode 810, a first source electrode 830, and a first drain electrode 840. The first gate electrode 810 is connected to the gate wiring 331. The first source electrode 830 is connected to the source wiring 321. The first drain electrode 840 is connected to the storage capacitor 890 and the liquid crystal element 410. The transistor Tr1 shown in the first embodiment is applied to the transistor 800 shown in FIG. 17. In the present embodiment, for convenience of explanation, although 830 is referred to as a source electrode and 840 is referred to as a drain electrode, the function of each electrode as a source and a drain may be replaced.

### EXAMPLES

### 3. Electrical Characteristics of Transistor Tr1

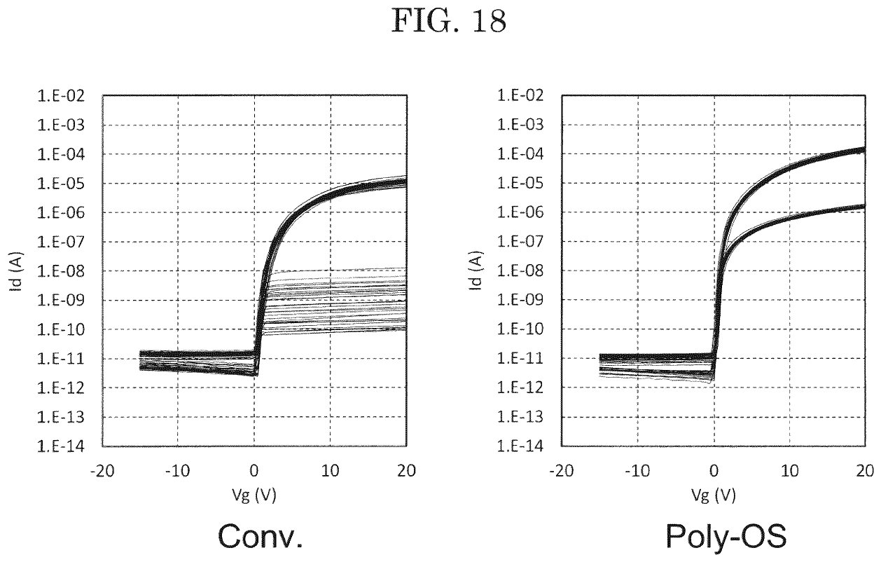

The electric properties of the transistor Tr1 will be described with reference to FIG. 18. FIG. 18 is a diagram showing electrical characteristics of a semiconductor device according to an embodiment of the present invention. FIG. 18 shows the electric properties of the conventional transistor (Conv.) and the transistor Tr1 (Poly-OS) according to the first embodiment. The conventional transistor has the same configuration as the transistor Tr1 of the first embodiment, and an amorphous oxide semiconductor layer is used as the oxide semiconductor layer OS. Therefore, in the conventional transistor, the crystallization of ITO used as the connecting electrode ZTCO does not vary depending on location.

Measurement conditions of the electrical characteristics shown in FIG. 18 are as follows.
Size of channel region CH: W/L=2.0 μm/2.5 μm
Source drain voltage: 0.1 V, 10 V
Gate voltage: −15 V to +20 V
Measurement environment: room temperature, dark room
Number of measurement points: 30

As shown in FIG. 18, in the conventional transistor, an abnormal value of an on-state current is confirmed in the plurality of transistors. In the transistor in which the abnormal value is confirmed, the on-state current is saturated, and the on-state current is not increased even if the gate voltage is increased. That is, it is considered that a high resistance portion exists in a current path of the transistor. On the other hand, in the transistor Tr1 according to the first embodiment, the abnormal value of the on-state current is not confirmed.

### 4. Contact Resistance

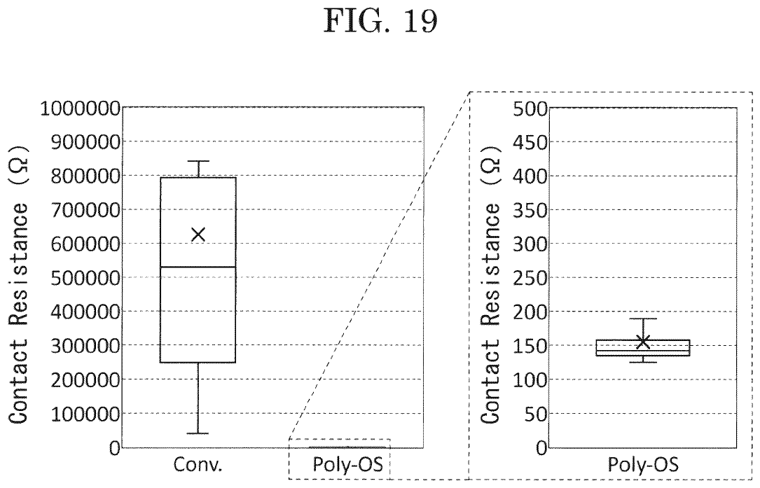

FIG. 19 is a diagram showing contact resistance values of the oxide semiconductor layer and the transparent conductive layer in the semiconductor device according to the embodiment of the present invention. FIG. 19 is a graph showing a test pattern (TEG) for measuring contact resistivity provided on each of the substrates of the conventional transistor (Conv.) and the transistor Tr1 (Poly-OS) according to the first embodiment.

FIG. 19 is a box-and-whisker plot showing the contact resistance described above. In FIG. 19, the maximum value (an upper end of a whisker), the minimum value (a lower end of a whisker), the distribution of the center 50% of the data (from an upper end to a lower end of a box), the average value (an x mark), and the median value (the boundary between the upper box and the lower box) in the measured contact resistance value are shown.

As shown in FIG. 19, in the conventional transistor, in most TEG, the contact resistivity between the oxide semiconductor layers OS and the connecting electrodes ZTCO exceeds 100 kΩ. On the other hand, in the transistor Tr1 according to the first embodiment, in all TEG, the contact resistor falls within a range of 100Ω to 200Ω.

As described above, in the transistor Tr1 according to the present embodiment, since the contact resistances between the oxide semiconductor layers OS and the connecting electrode ZTCO are very low, it has been found that the on-state current is not saturated and normal electric properties are obtained.

Each of the embodiments described above as an embodiment of the present invention can be appropriately combined and implemented as long as they do not contradict each other. Further, the addition, deletion, or design change of components as appropriate by those skilled in the art based on each embodiment are also included in the scope of the present invention as long as they are provided with the gist of the present invention.

It is understood that, even if the effect is different from those provided by each of the embodiments described above, the effect obvious from the description in the specification or easily predicted by persons ordinarily skilled in the art is apparently derived from the present invention.

What is claimed is:

1. A semiconductor device comprising:
an oxide semiconductor layer including a polycrystalline structure;
a gate electrode facing the oxide semiconductor layer;
a gate insulating layer between the oxide semiconductor layer and the gate electrode;
a first transparent conductive layer connected to the oxide semiconductor layer, and
a second transparent conductive layer arranged in the same layer as the first transparent conductive layer and separated from the first transparent conductive layer,
wherein
crystallizability of the first transparent conductive layer is different from crystallizability of the second transparent conductive layer.

2. The semiconductor device according to claim 1,
wherein
each of the first transparent conductive layer and the second transparent conductive layer includes indium and tin.

3. The semiconductor device according to claim 1,
wherein
the oxide semiconductor layer includes two or more metals including indium, and
a ratio of indium in the two or more metal is 50% or more.

4. The semiconductor device according to claim 1,
wherein
the gate electrode, the first transparent conductive layer, and the second transparent conductive layer are arranged above the oxide semiconductor layer.

5. The semiconductor device according to claim 1, further comprising:
a first insulating layer arranged above the oxide semiconductor layer and the gate electrode and arranged with a first opening;
a metal layer arranged above the first insulating layer and connected to the oxide semiconductor layer via the first opening, and
a second insulating layer arranged above the first insulating layer,
wherein
the first insulating layer and the second insulating layer are arranged with a second opening, and
the first transparent conductive layer is connected to the oxide semiconductor layer via the second opening.

6. The semiconductor device according to claim 1, further comprising:
an insulating layer in contact with bottom surfaces of the first transparent conductive layer and the second transparent conductive layer.

7. A semiconductor device comprising:
an oxide semiconductor layer including a polycrystalline structure;
a gate electrode opposed to the oxide semiconductor layer;
a gate insulating layer between the oxide semiconductor layer and the gate electrode; and
a first transparent conductive layer connected to the oxide semiconductor layer in a first region in a plan view,
wherein
crystallizability of the first transparent conductive layer in the first region is different from crystallizability of the first transparent conductive layer in a second region, is the second region being different from the first region.

8. The semiconductor device according to claim 7,
wherein
the first transparent conductive layer includes indium and tin.

9. The semiconductor device according to claim 7,
wherein
the oxide semiconductor layer includes two or more metals including indium, and
a ratio of indium in the two or more metal is 50% or more.

10. The semiconductor device according to claim 7,
wherein
the gate electrode and the first transparent conductive layer are arranged above the oxide semiconductor layer.

11. The semiconductor device according to claim 7, further comprising:
a first insulating layer arranged above the oxide semiconductor layer and the gate electrode and arranged with a first opening;
a metal layer arranged above the first insulating layer and connected to the oxide semiconductor layer via the first opening; and
a second insulating layer arranged above the first insulating layer,
wherein
the first insulating layer and the second insulating layer are arranged with a second opening, and
the first transparent layer is connected to the oxide semiconductor layer via the second opening.

12. The semiconductor device according to claim 7,
wherein
the first transparent conductive layer in the first region and the first transparent conductive layer in the second region are continuous.
